(19) United States
(12) Patent Application Publication
(10) Pub. No.: US 2020/0020550 A1
(43) Pub. Date: Jan. 16, 2020

(54) SUBSTRATE PROCESSING APPARATUS AND SUBSTRATE PROCESSING METHOD

(71) Applicant: Tokyo Electron Limited, Tokyo (JP)

(72) Inventors: Gentaro Goshi, Koshi-shi, Kumamoto (JP); Keisuke Egashira, Koshi-shi, Kumamoto (JP); Kento Tsukano, Koshi-shi, Kumamoto (JP); Hiroshi Marumoto, Koshi-shi, Kumamoto (JP)

(21) Appl. No.: 16/495,142

(22) PCT Filed: Mar. 13, 2018
(86) PCT No.: PCT/JP2018/009797

§ 371 Date: Sep. 18, 2019

(30) Foreign Application Priority Data
Mar. 21, 2017 (JP) 2017-054128

(51) Int. Cl. H01L 21/67; H01L 21/66; H01L 21/02; B08B 7/00

(52) U.S. Cl. CPC H01L 21/67034; H01L 21/67253; B08B 7/0021; H01L 21/02101; H01L 22/26

(57) ABSTRACT

A substrate processing apparatus 1 includes a drying processing unit 17, a drain line L2, an acquisition device 75 and a determination unit 19C. The drying processing unit 17 is configured to perform, by bringing a supercritical fluid into contact with a substrate having a surface wet by a liquid to replace the liquid with the supercritical fluid, a drying processing on the substrate. The drain line L2 is provided in the drying processing unit 17, and configured to drain the fluid from the drying processing unit 17. The acquisition device 75 is provided on the drain line L2, and configured to acquire optical information upon the fluid drained from the drying processing unit 17. The determination unit 19C is configured to detect presence or absence of the liquid within the drying processing unit 17 based on the optical information acquired by the acquisition device 75.

### TECHNICAL FIELD

The various aspects and embodiments described herein pertain generally to a substrate processing apparatus and a substrate processing method.

### BACKGROUND

Conventionally, there is known a substrate processing apparatus configured to form a dry-prevention liquid film on a surface of a substrate and perform a drying processing by bringing the substrate having the liquid film formed thereon into contact with a supercritical fluid to replace a liquid forming the liquid film with the supercritical fluid (see, for example, Patent Document 1).

### PRIOR ART DOCUMENT

Patent Document 1: Japanese Patent Laid-open Publication No. 2013-012538

### DISCLOSURE OF THE INVENTION

In this substrate processing apparatus, however, there is still a room for improvement in that a determination upon whether the drying processing is appropriately ended as the liquid on the surface of the substrate within a drying processing unit in which the drying processing is performed is used up needs to be made.

Exemplary embodiments provide a substrate processing apparatus and a substrate processing method of detecting presence or absence of a liquid within a drying processing unit in which a drying processing is performed.

### Means for Solving the Problems

In one exemplary embodiment, a substrate processing apparatus includes a drying processor, a drain line, an acquisition unit and a detector. The drying processor is configured to perform, by bringing a supercritical fluid into contact with a substrate having a surface wet by a liquid to replace the liquid with the supercritical fluid, a drying processing on the substrate. The drain line is provided in the drying processor. The fluid is drained from the drying processor through the drain line. The acquisition unit is provided on the drain line, and configured to acquire optical information upon the fluid drained from the drying processor. The detector is configured to detect presence or absence of the liquid within the drying processor based on the optical information acquired by the acquisition unit.

According to the exemplary embodiment, it is possible to detect the presence or absence of the liquid within the drying processor.

### BRIEF DESCRIPTION OF THE DRAWINGS

FIG. 1 is a diagram illustrating a schematic configuration of a substrate processing system according to a first exemplary embodiment.

FIG. 2 is a cross sectional view illustrating a configuration of a cleaning processing unit.

FIG. 3 is an exterior perspective view illustrating a configuration of a drying processing unit.

FIG. 4 is a diagram illustrating a configuration example of an entire system of the drying processing unit.

FIG. 5 is a cross sectional view illustrating a configuration of a sight glass.

FIG. 6 is a block diagram illustrating a schematic configuration of a control device configured to detect presence or absence of a liquid.

FIG. 7 is a diagram schematically illustrating an image of a supercritical fluid photographed by a camera.

FIG. 8 a flowchart showing a processing sequence of a drying processing according to the first exemplary embodiment.

FIG. 9 is a flowchart showing a processing sequence of a drying processing according to a second exemplary embodiment.

### DETAILED DESCRIPTION

Hereinafter, exemplary embodiment of a substrate processing apparatus and a substrate processing method according to the present disclosure will be described in detail. However, it should be noted that the present disclosure is not limited to the following exemplary embodiments.

### First Exemplary Embodiment

<Outline of Substrate Processing System 1>

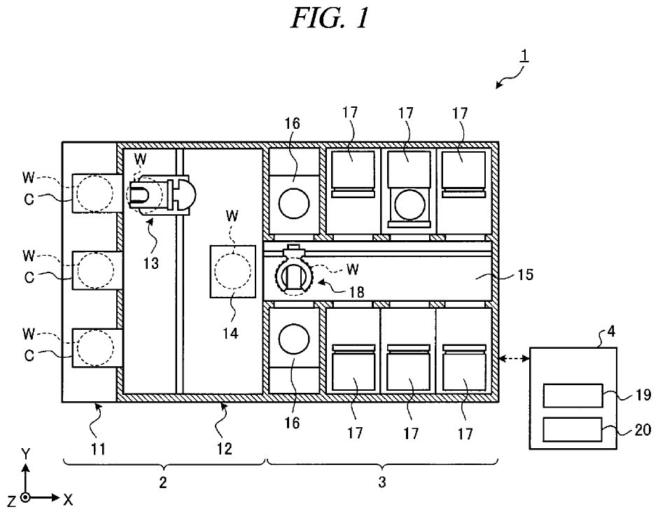

Referring to FIG. 1, a schematic configuration of a substrate processing system (substrate processing apparatus) 1 according to a first exemplary embodiment will be explained. FIG. 1 is a diagram illustrating the schematic configuration of the substrate processing system 1 according to the first exemplary embodiment. In the following, in order to clarify positional relationships, the X-axis, Y-axis and Z-axis which are orthogonal to each other will be defined, and the positive Z-axis direction will be regarded as a vertically upward direction.

The substrate processing system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, carriers C each accommodating semiconductor wafers W (hereinafter, referred to as “wafers W”) horizontally are placed.

The transfer section 12 is provided adjacent to the carrier placing section 11, and incorporates therein a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafer W between the carrier C and the delivery unit 14 by using the wafer holding mechanism.

The processing station 3 is provided adjacent to the transfer section 12. The processing station 3 is provided with a transfer block 15, a plurality of cleaning processing units 16 and a plurality of drying processing units (drying processors) 17. The cleaning processing units 16 and the drying processing units 17 are arranged at both sides of the transfer block 15. Further, the layout and the number of the cleaning processing units 16 and the drying processing units 17 shown in FIG. 1 are nothing more than an example and are not limited thereto.

The transfer block 15 has therein a substrate transfer device 18. The substrate transfer device 18 is provided with a wafer holding mechanism configured to hold the wafer W. Further, the substrate transfer device 18 is movable horizontally and vertically and pivotable around a vertical axis. The substrate transfer device 18 transfers the wafer W between the delivery unit 14, the cleaning processing unit 16 and the drying processing unit 17.

The cleaning processing unit 16 is configured to perform a preset cleaning processing on the wafer W transferred by the substrate transfer device 18.

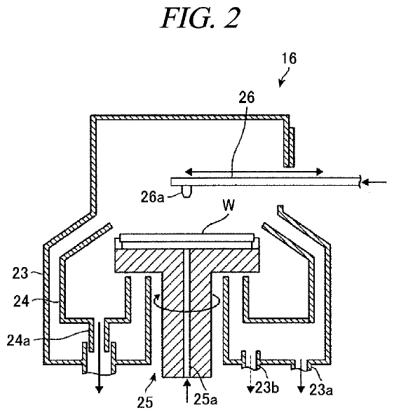

The cleaning processing unit 16 will be explained with reference to FIG. 2. FIG. 2 is a cross sectional view illustrating a configuration of the cleaning processing unit 16. The cleaning processing unit 16 is configured as a single-wafer type cleaning processing unit configured to clean the wafers W one by one by, for example, spin cleaning.

The cleaning processing unit 16 holds the wafer W substantially horizontally with a wafer holding mechanism 25 provided within an outer chamber 23 forming a processing space therein, and rotates the wafer W by rotating this wafer holding mechanism 25 around a vertical axis. Further, in the cleaning processing unit 16, a nozzle arm 26 is advanced to a space above the wafer W being rotated, and by supplying a chemical liquid and a rinse liquid in a preset sequence from a chemical liquid nozzle 26a provided at a leading end of the nozzle arm 26, the cleaning processing on a surface of the wafer W is performed.

Furthermore, in the cleaning processing unit 16, a chemical liquid supply path 25a is formed within the wafer holding mechanism 25. A rear surface of the wafer W is cleaned by the chemical liquid and the rinse liquid supplied form this chemical liquid supply path 25a.

In the aforementioned cleaning processing of the wafer W, a particle or an organic contaminant is first removed by, for example, SC1 solution (a mixed solution of ammonia and hydrogen peroxide water) as an alkaline chemical liquid. Then, a rinse cleaning is performed by using deionized water (hereinafter, referred to as “DIW”) as the rinse liquid. Thereafter, a natural oxide film is removed by diluted hydrofluoric acid as an acidic chemical liquid, and a rinse cleaning by DIW is then performed.

The aforementioned various kinds of chemical liquids are received by the outer chamber 23 and an inner cup 24 disposed within the outer chamber 23, and then, drained from a drain port 23a provided at a bottom of the outer chamber 23 and a drain port 24a provided at a bottom of the inner cup 24. Further, an atmosphere within the outer chamber 23 is exhausted through an exhaust port 23b provided at the bottom of the outer chamber 23.

Upon the completion of the above-stated rinsing processing of the wafer W, by supplying an IPA liquid to the front surface and the rear surface of the wafer W while rotating the wafer holding mechanism 25, the DIW remaining on the front surface and the rear surface of the wafer W is replaced by the IPA. Thereafter, the rotation of the wafer holding mechanism 25 is stopped gently.

A liquid film of the IPA liquid is formed on the front surface of the wafer W after being subjected to the cleaning processing. This wafer W having the liquid film formed thereon is delivered to the substrate transfer device 18 by a non-illustrated delivery mechanism provided in the wafer holding mechanism 25, and then, is taken out of the cleaning processing unit 16.

The liquid film formed on the front surface of the wafer W serves as a liquid for dry prevention which suppresses the liquid on the front surface of the wafer W from being evaporated (vaporized) and thus causing a pattern collapse during the transfer of the wafer W into the drying processing unit 17 from the cleaning processing unit 16 and during the carrying-in operation of the wafer W into the drying processing unit 17.

Referring back to FIG. 1, the drying processing unit 17 is configured to perform a drying processing on the wafer W, which is cleaned by the cleaning processing unit 16, by using a supercritical fluid. In the drying processing, by bringing a supercritical fluid of CO₂ into contact with the IPA liquid on the wafer W, the IPA liquid dissolved into the supercritical fluid to be removed. Accordingly, the wafer W is dried.

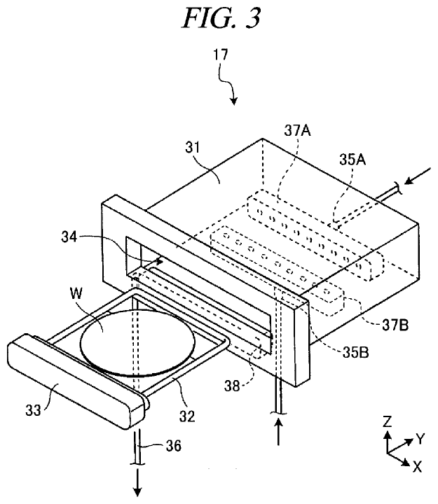

The drying processing unit 17 will be explained with reference to FIG. 3. FIG. 3 is an exterior perspective view illustrating a configuration of the drying processing unit 17.

The drying processing unit 17 is equipped with a main body 31, a holding plate 32 and a cover member 33. The main body 31 having a housing shape is provided with an opening 34 through which the wafer W is carried in or out. The holding plate 32 is configured to hold the wafer W as a processing target horizontally. The cover member 33 is configured to support the holding plate 32 and seal the opening 34 when the wafer W is carried into the main body 31.

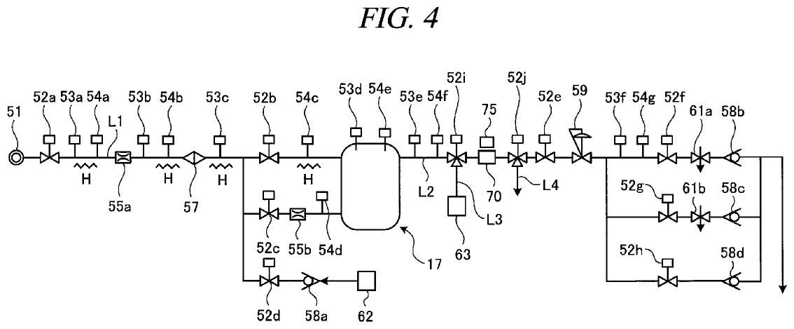

The main body 31 is a vessel having therein a processing space in which the wafer W can be accommodated. The main body 31 is provided with supply ports 35A and 35B and a drain port 36 at walls thereof. The supply ports 35A and 35B are connected to a supply line L1 (see FIG. 4) through which the supercritical fluid is flown. The drain port 36 is connected to a drain line L2 (see FIG. 4) through which the supercritical fluid is drained out.

The supply port 35A is connected to a side surface of the housing-shaped main body 31 opposite to a side surface where the opening 34 is provided. Further, the supply port 35B is connected to a bottom surface of the main body 31. Further, the drain port 36 is connected to a portion of the main body 31 under the opening 34. Here, although the two supply ports 35A and 35B and the single drain port 36 are illustrated in FIG. 3, the numbers of the supply ports 35A and 35B and the drain port 36 are not particularly limited.

Further, fluid supply headers 37A and 37B and a fluid drain header 38 are provided within the main body 31. Each of the fluid supply headers 37A and 37B and the fluid drain header 38 is provided with a multiple number of openings.

The fluid supply header 37A is connected to the supply port 35A. Within the housing-shaped main body 31, the fluid supply header 37A is provided adjacent to the side surface of the main body 31 opposite to the opening 34. Further, the multiple number of openings formed at the fluid supply header 37A are directed toward the opening 34.

The fluid supply header 37B is connected to the supply port 35B. Within the housing-shaped main body 31, the fluid supply header 37B is provided at a central portion of the bottom surface of the housing-shaped main body 31. The multiple number of openings formed at the fluid supply header 37B face upwards.

The fluid drain header 38 is connected to the drain port 36. Within the housing-shaped main body 31, the fluid drain header 38 is provided adjacent to the side surface of the main body 31 near the opening 34 and is positioned under the opening 34. Further, the multiple number of openings formed at the fluid drain header 38 are directed toward the fluid supply header 37A.

The fluid supply headers 37A and 37B are configured to supply the supercritical fluid into the main body 31. Further, the fluid drain header 38 is configured to guide and drain the supercritical fluid within the main body 31 to the outside thereof. Further, the supercritical fluid drained out to the outside of the main body 31 through the fluid drain header 38 includes the IPA liquid dissolved into the supercritical fluid from the surface of the wafer W.

The drying processing unit 17 is further equipped with a non-illustrated pressing mechanism. The pressing mechanism has a function of sealing the processing space by pressing the cover member 33 toward the main body 31 against an internal pressure caused by the supercritical fluid in a supercritical state supplied into the processing space within the main body 31. Further, to allow the supercritical fluid supplied into the processing space to maintain a preset temperature, an insulator, a tape heater, or the like may be provided on the surface of the main body 31.

Now, a configuration of an entire system of the drying processing unit 17 will be explained with reference to FIG. 4. FIG. 4 is a diagram illustrating a configuration example of the entire system of the drying processing unit 17.

In the entire system of the drying processing unit 17, a fluid source 51 is provided upstream of the drying processing unit 17. Further, the supply line L1 connects the fluid source 51 and the drying processing unit 17, and the supercritical fluid is flown in the drying processing unit 17 through this supply line L1. The supercritical fluid from the fluid source 51 is supplied into the supply line L1. The fluid source 51 stores therein, for example, source CO₂ for generating the supercritical fluid of CO₂.

Further, the supply line L1 is provided with a valve 52a, an orifice 55a, a filter 57 and a valve 52b in sequence from an upstream side toward a downstream side. Here, the terms “upstream side” and “downstream side” used herein are defined with respect to a flow direction of the supercritical fluid in the supply line L1 and the drain line L2.

The valve 52a is configured to control on and off of the supply of the supercritical fluid from the fluid source 51. In an open state, the valve 52a allows the supercritical fluid to be flown to the supply line L1 located at the downstream side thereof, whereas in an off sate, the valve 52a does not allow the supercritical fluid to be flown to the supply line L1 located at the downstream side thereof. By way of example, when the valve 52a is opened, the supercritical fluid having a high pressure ranging from 16 MPa to 20 MPa is supplied into the supply line L1 from the fluid source 51 via the valve 52a.

The orifice 55a has a function of adjusting the pressure of the supercritical fluid supplied from the fluid source 51. By way of example, the orifice 55a is capable of allowing the supercritical fluid to be flown to the supply line L1 located at a downstream side of the orifice 55a at an adjusted pressure of about 16 MPa.

The filter 57 is configured to remove a foreign substance included in the supercritical fluid sent from the orifice 55a, and allows the clean supercritical fluid to be flown to the downstream side thereof.

The valve 52b is configured to control on and off of the supply of the supercritical fluid into the drying processing unit 17. The supply line L1 connected from the valve 52b to the drying processing unit 17 is coupled to the supply port 35A shown in FIG. 3, and the supercritical fluid flowing through the valve 52b is supplied into the main body 31 via the supply port 35A and the fluid supply header 37A.

Further, in the entire system of the drying processing unit 17 shown in FIG. 4, the supply line L1 is branched between the filter 57 and the valve 52b. To elaborate, a supply line L1 connected to the drying processing unit 17 via a valve 52c and an orifice 55b and a supply line L1 connected to a purging apparatus 62 via a valve 52d and a check valve 58a are branched to extend from the supply line L1 between the filter 57 and the valve 52b.

The supply line L1 connected to the drying processing unit 17 via the valve 52c and the orifice 55b is an auxiliary flow path for the supply of the supercritical fluid into the drying processing unit 17. This supply line L1 as the auxiliary flow path is connected to the supply port 35B shown in FIG. 3, and the supercritical fluid flown through the valve 52c is supplied into the main body 31 via the supply port 35B and the fluid supply header 37B.

The supply line L1 connected to the purging apparatus 62 via the valve 52d and the check valve 58a is a flow path through which an inert gas such as a nitrogen gas is supplied into the drying processing unit 17. By way of example, this supply line L1 is used when the supply of the supercritical fluid from the fluid source 51 to the drying processing unit 17 is stopped.

For example, when maintaining the drying processing unit 17 in a clean state filled with the inert gas, the valve 52d and the valve 52b are controlled to be opened, and the inert gas sent from the purging apparatus 62 into the supply line L1 is supplied into the drying processing unit 17 via the check valve 58a, the valve 52d and the valve 52b.

In the entire system of the drying processing unit 17, the drain line L2 through which the supercritical fluid is drained from the drying processing unit 17 is provided at the downstream side of the drying processing unit 17.

The drain line L2 is provided with a switching valve 52i, a sight glass 70, a switching valve 52j, a valve 52e, an exhaust control valve 59 and a valve 52f in sequence from the upstream side toward the downstream side thereof. The drain line L2 is connected to the drain port 36, and the supercritical fluid within the main body 31 of the drying processing unit 17 is sent toward the valve 52e via the fluid drain header 38 and the drain port 36 shown in FIG. 3.

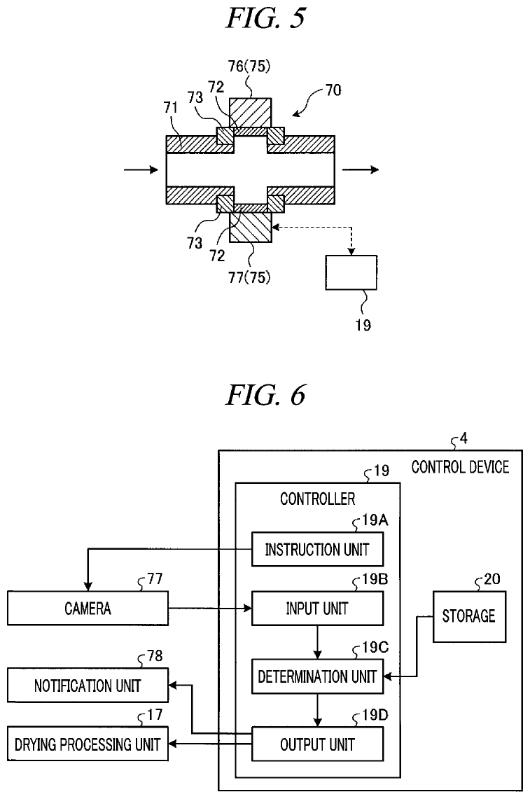

The sight glass 70 is equipped with, as depicted in FIG. 5, a pipe member 71, a pair of transmitting windows 72 and a pair of frames 73 configured to support the transmitting windows 72 and mount the transmitting windows 72 to the pipe member 71. FIG. 5 is a cross sectional view illustrating a configuration of the sight glass 70. The pipe member 71 communicates with the drain line L2. The pair of transmitting windows 72 is disposed to face each other. The pipe member 71 may be formed as single body with the drain line L2.

An acquisition device 75 configured to acquire optical information of the supercritical fluid drained from the drying processing unit 17 is provided at an outside of the sight glass 70.

The acquisition device 75 includes a light source 76 and a camera 77. The light source 76 irradiates light toward the inside of the pipe member 71 from an outside of one of the pair of transmitting windows 72. The camera 77 has an imaging device such as COMS (Complementary Metal Oxide Semiconductor) or CCD (Charge Coupled Device). The camera 77 images the inside of the pipe member 71 from the other one of the transmitting windows 72. The camera 77 images the supercritical fluid drained from the drying processing unit 17. Image data obtained by this imaging is outputted to a controller 19.

The sight glass 70 and the acquisition device 75 may be provided at the drain line L2 downstream of, for example, the valve 52e.

Referring back to FIG. 4, the switching valve 52i is a three-way valve configured to switch a fluid flown to the sight glass 70. The switching valve 52i allows the supercritical fluid to be flown to the sight glass 70 from the drying processing unit 17 in the drying processing, whereas the switching valve 52i allows a cleaning liquid such as IPA or DIW to be flown to the sight glass 70 from a cleaning liquid source (cleaning liquid supply) 63 via a cleaning liquid supply line L3 in the cleaning processing.

The switching valve 52j is a three-way valve configured to switch a flow direction (drain direction) of the fluid flown through the sight glass 70. In the drying processing, the switching valve 52j allows the supercritical fluid to be flown to the drain line L2 downstream of the switching valve 52j from the sight glass 70. In the cleaning processing, the switching valve 52j allows the cleaning liquid to be flown to a cleaning liquid drain line L4 through which the cleaning liquid is drained from the sight glass 70. Further, each of the switching valve 52i and the switching valve 52j may be formed of a combination of two valves. By way of example, the two valves may be respectively provided at the cleaning liquid supply line L3 and the drain line L2 upstream of a point where the cleaning liquid line L3 joins the drain line L2.

The valve 52e is configured to control on and off of the drain of the supercritical fluid from the drying processing unit 17. When the drain of the supercritical fluid from the drying processing unit 17 is performed, the valve 52e is opened. When the supercritical fluid is not drained from the drying processing unit 17, the valve 52e is kept closed.

The exhaust control valve 59 is configured to control the drain amount of the supercritical fluid from the drying processing unit 17, and may be composed of, by way of example, a back pressure valve. A degree of openness of the exhaust control valve 59 is adjusted adaptively based on a required drain amount of the supercritical fluid from the main body 31 under the control of a control device 4.

The valve 52f is configured to control on and off of the drain of the supercritical fluid from the drying processing unit 17 to the outside thereof. When draining the supercritical fluid to the outside of the drying processing unit 17, the valve 52f is opened. When the drain of the supercritical fluid is not performed, the valve 52f is kept closed. Further, an exhaust control needle valve 61a and a check valve 58b are provided downstream of the valve 52f.

The exhaust control needle valve 61a is configured to adjust the drain amount of the supercritical fluid sent from the valve 52f to the outside. A degree of openness of the exhaust control needle valve 61a is adjusted based on a required drain amount of the supercritical fluid. The check valve 58b is a valve configured to suppress a backflow of the supercritical fluid being drained, and has a function of allowing the supercritical fluid to be drained to the outside securely.

Further, in the drying processing unit 17 shown in FIG. 4, the drain line L2 is branched between the exhaust control valve 59 and the valve 52f. To elaborate, a drain line L2 connected to the outside via a valve 52g and a drain line L2 connected to the outside via a valve 52h are branched to extend from the drain line L2 between the exhaust control valve 59 and the valve 52f.

Like the valve 52f, the valve 52g and the valve 52h are configured to control on and off of the drain of the supercritical fluid to the outside. An exhaust control needle valve 61b and a check valve 58c are provided downstream of the valve 52g to control the drain amount of the supercritical fluid and suppress the backflow of the supercritical fluid. A check valve 58d is provided downstream of the valve 52h to suppress the backflow of the supercritical fluid.

When draining the supercritical fluid from the drying processing unit 17, one or more of the valves 52f, 52g and 52h are controlled to be opened. Here, in the entire system of the drying processing unit 17, by performing the drain of the supercritical fluid to the outside through the multiple valves (valves 52f, 52g and 52h), the drain amount of the supercritical fluid to the outside of the drying processing unit 17 can be controlled precisely.

Further, pressure sensors each configured to detect a pressure of the supercritical fluid and temperature sensors each configured to detect a temperature of the supercritical fluid are provided at various positions on the supply line L1 and the drain line L2. In the example shown in FIG. 4, a pressure sensor 53a and a temperature sensor 54a are provided between the valve 52a and the orifice 55a, and a pressure sensor 53b and a temperature sensor 54b are provided between the orifice 55a and the filter 57.

Furthermore, a pressure sensor 53c is provided between the filter 57 and the valve 52b, and a temperature sensor 54c is provided between the valve 52b and the drying processing unit 17. Further, a temperature sensor 54d is provided between the orifice 55b and the drying processing unit 17, and a temperature sensor 54e is provided at the drying processing unit 17.

Moreover, a pressure sensor 53d and a temperature sensor 54f are provided between the drying processing unit 17 and the valve 52e, and a pressure sensor 53e and a temperature sensor 54g are provided between the exhaust control valve 59 and the valve 52f.

In addition, heaters H are provided at portions of the drying processing unit 17 where the supercritical fluid flows. In the example shown in FIG. 4, the heaters H are respectively provided between the valve 52a and the orifice 55a, between the orifice 55a and the filter 57, between the filter 57 and the valve 52b and between the valve 52b and the drying processing unit 17 on the supply line L1.

Meanwhile, heaters H may also be provided at the drying processing unit 17 and other portions including the drain line L2. That is, the heater H may be provided at the entire flow path through which the supercritical fluid supplied from the fluid source 51 is drained to the outside.

In the above-described system of the drying processing unit 17, the supercritical fluid is supplied into the main body 31 of the drying processing unit 17 through the supply line L1, thus turning the inside of the main body 31 into the supercritical state. Then, by supplying the supercritical fluid while draining the supercritical fluid through the drain line L2, the inside of the main body 31 is maintained in the supercritical state and the IPA on the wafer W is gradually replaced by the supercritical fluid.

Referring back to FIG. 1, the substrate processing system 1 is equipped with the control device 4. The control device 4 is, for example, a computer, and equipped with the controller 19 and a storage 20.

The storage 20 is implemented by a semiconductor memory device such as, but not limited to, a RAM (Random Access Memory) or a flash memory (Flash memory), or a storage device such as, but not limited to, a hard disk, an optical disk, or the like.

The controller 19 includes a microcomputer having a CPU (Central Processing Unit), a ROM (Read Only Memory), a RAM, an input/output port, and so forth and various kinds of circuits. The CPU of the microcomputer implements the controls over the substrate transfer devices 13 and 18, the cleaning processing unit 16, the drying processing unit 17, and so forth by reading out a program stored in the ROM and executing the program. Further, the controller 19 receives measurement results of the individual sensors and outputs instruction signals to control the individual valves based on the measurement results.

Further, the program may be recorded on a computer-readable recording medium and installed from the recording medium to the storage 20 of the control device 4. The computer-readable recording medium may be, by way of non-limiting example, a hard disk HD, a flexible disk FD, a compact disk CD, a magnetic optical disk MO, a memory card, or the like.

Here, a configuration of the control device 4 configured to detect the presence or absence of the IPA (liquid) based on the optical information of the supercritical fluid will be explained with reference to FIG. 6. FIG. 6 is a block diagram illustrating a schematic configuration of the control device 4 configured to detect the presence or absence of the IPA. The controller 19 is equipped with an instruction unit 19A, an input unit 19B, a determination unit (detector) 19C and an output unit 19D.

The instruction unit 19A outputs an instruction of imaging the supercritical fluid to the camera 77 upon a lapse of a completion time after the drying processing by the drying processing unit 17 is begun. The completion time is a preset time, and is a time required until the IPA on the wafer W is replaced with the supercritical fluid.

The input unit 19B receives image data of the supercritical fluid acquired by the camera 77.

The determination unit 19C compares the acquired image data with reference image data stored in the storage 20 and determines whether the IPA on the wafer W is replaced with the supercritical fluid. The reference image data is image data of the supercritical fluid in which the IPA is not included.

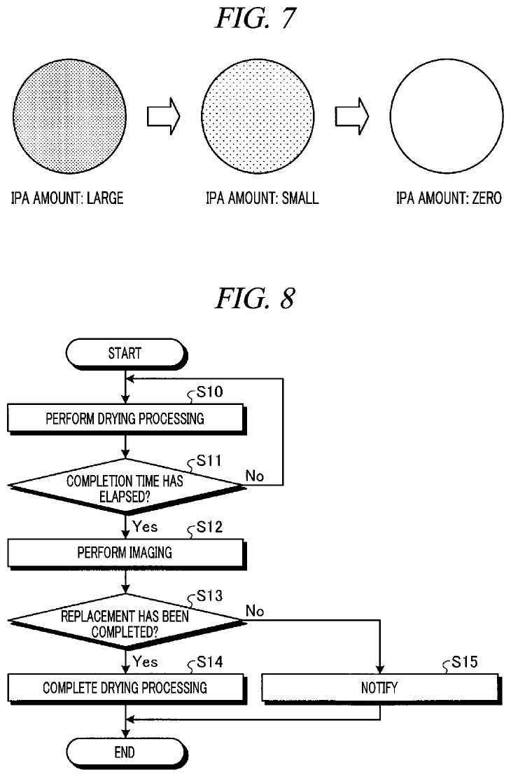

Here, a relationship between an IPA amount included in the supercritical fluid and an image of the supercritical fluid obtained by the camera 77 will be described with reference to FIG. 7. FIG. 7 is a diagram schematically illustrating the image of the supercritical fluid obtained by the camera 77.

If the IPA amount included in the supercritical fluid is large, the image captured by the camera 77 is dark. As the IPA amount decreases, that is, as the IPA on the wafer W is replaced by the supercritical fluid, the image captured by the camera 77 becomes bright and white.

It is because the supercritical fluid including only the CO₂ easily transmit the light whereas the supercritical fluid including the IPA does not easily transmit the light as compared to the supercritical fluid including only the CO₂.

The determination unit 19C compares color information (at least one of color, chroma and brightness) of the image data obtained by the camera 77 with color information (at least one of color, chroma and brightness) of the reference image data, and makes a determination that the IPA on the wafer W has not been replaced by the supercritical fluid if a difference between the color information of the obtained image data and the color information of the reference image data is larger than a predetermined threshold value. If the difference between the color information of the obtained image data and the color information of the reference image data is equal to or less than the predetermined threshold value, the determination unit 19C makes a determination that the IPA on the wafer W has been replaced by the supercritical fluid. In this way, the determination unit 19C detects the presence or absence of the IPA within the drying processing unit 17 based on the optical information of the supercritical fluid.

If the IPA on the wafer W has not been replaced by the supercritical fluid even after the lapse of the completion time after the beginning of the drying processing, the determination unit 19C makes a determination that the drying processing is abnormal.

The output unit 19D outputs an alarm signal to a notification unit 78 if the IPA on the wafer W has not been replaced by the supercritical fluid even after the lapse of the completion time after the beginning of the drying processing.

In response to the alarm signal, the notification unit 78 makes a notification indicating the abnormality of the drying processing. The notification unit 78 may be an alarm light or a monitor. For example, when the drying processing is abnormal, the alarm light may be turned on and off, or a message indicating the abnormality may be displayed on the monitor.

If the IPA on the wafer W has been replaced by the supercritical fluid upon the lapse of the completion time after the beginning of the drying processing, the output unit 19D outputs a drying processing completion signal to the drying processing unit 17.

<Drying Processing>

Now, the drying processing in the substrate processing system 1 according to the first exemplary embodiment will be described with reference to FIG. 8. FIG. 8 is a flowchart showing a processing sequence of the drying processing according to the first exemplary embodiment.

If the cleaning processing is ended and the wafer W having the liquid film formed thereon is carried into the main body 31 of the drying processing unit 17, the substrate processing system 1 performs a drying processing (S10). As the drying processing progresses, the IPA on the wafer W is gradually replaced by the supercritical fluid.

The substrate processing system 1 carries on the drying processing until the completion time elapses after the beginning of the drying processing (S11: No). Upon the lapse of the completion time after the beginning of the drying processing (S11: Yes), the supercritical fluid is imaged by the camera 77 (S12).

Then, the substrate processing system 1 compares the image data obtained by this imaging operation and the reference image data and makes the determination upon whether the IPA on the wafer W has been replaced by the supercritical fluid (S13). That is, the substrate processing system 1 determines whether an abnormality has occurred in the drying processing.

If the replacement is completed and no abnormality is found in the drying processing (S13: Yes), the substrate processing system 1 lowers the pressure within the main body 31 to the atmospheric pressure and ends the drying processing (S14).

If the replacement is not completed and the abnormality is found in the drying processing (S13: No), the substrate processing system 1 notifies the occurrence of the abnormality in the drying processing through the notification unit 78 (S15).

<Effects of First Exemplary Embodiment>

The substrate processing system 1 is capable of imaging the supercritical fluid drained from the drying processing unit 17 and detecting the presence or absence of the IPA (liquid) within the drying processing unit 17 based on the obtained image data.

The substrate processing system 1 images the supercritical fluid by the camera 77 upon the lapse of the completion time after the beginning of the drying processing in the drying processing unit 17. Then, the substrate processing system 1 compares the obtained image data with the reference image data. If the IPA has not been replaced by the supercritical fluid even after the lapse of the completion time and the abnormality is found in the drying processing, the notification unit 78 makes the alarm indicating the abnormality. Accordingly, when the abnormality has occurred in the drying processing, the occurrence of the abnormality can be detected accurately, and the appropriate alarm indicating the occurrence of the abnormality can be made.

In the substrate processing system 1, by imaging the supercritical fluid by the camera 77, the presence or absence of the IPA can be detected.

In the substrate processing system 1, by supplying the cleaning liquid into the drain line L2, the transmitting windows 72 of the sight glass 70 is cleaned. Accordingly, the deposit adhering to the transmitting windows 72 of the sight glass 70 can be washed away, and the clear image of the supercritical fluid can be obtained by the camera 77. Thus, the detection of the presence or absence of the IPA can be performed appropriately.

### Second Exemplary Embodiment

<Configuration of Substrate Processing System 1>

Now, a substrate processing system 1 according to a second exemplary embodiment will be described. In the substrate processing system 1 according to the second exemplary embodiment, a control device 4 configured to detect the presence or absence of the IPA based on the optical information of the supercritical fluid is different from that of the first exemplary embodiment. Here, the description will be focused on the control device 4. Further, a schematic configuration of the control device 4 is the same as that of the first exemplary embodiment, and the description will be made with reference to FIG. 6.

If the drying processing by the drying processing unit 17 is begun, the instruction unit 19A outputs the instruction to image the supercritical fluid by the camera 77. The instruction unit 19A outputs this instruction at a preset interval. In response to these instructions, the camera 77 images the supercritical fluid at the preset interval.

The determination unit 19C compares the image data obtained at the preset internal with the reference image data stored in the storage 20, and makes the determination upon whether the IPA on the wafer W has been replaced by the supercritical fluid.

Further, the determination unit 19C also determines whether the completion time has elapsed after the beginning of the drying processing.

The output unit 19D outputs a replacement completion instruction to the drying processing unit 17 if the IPA on the wafer W has been replaced by the supercritical fluid. If, however, the IPA on the wafer W has not been replaced by the supercritical fluid even after the lapse of the completion time after the beginning of the drying processing, the output unit 19D outputs the alarm signal to the notification unit 78.

As stated above, in the second exemplary embodiment, the progress of the drying processing is determined based on the image data obtained by imaging the supercritical fluid. The drying processing is ended at a timing when the IPA on the wafer W has been replaced by the supercritical fluid.

<Drying Processing>

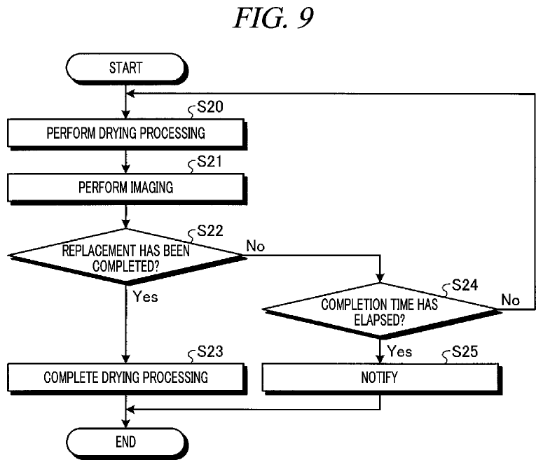

Now, the drying processing in the substrate processing system 1 according to the second exemplary embodiment will be described with reference to FIG. 9. FIG. 9 is a flowchart illustrating a processing sequence of the drying processing according to the second exemplary embodiment.

If the cleaning processing is ended and the wafer W having the liquid film formed thereon is carried into the main body 31 of the drying processing unit 17, the substrate processing system 1 performs the drying processing (S20).

The substrate processing system 1 images the supercritical fluid by the camera 77 (S21). Then, the substrate processing system 1 compares the image data obtained by this imaging operation and the reference image data and makes the determination upon whether the IPA on the wafer W has been replaced by the supercritical fluid (S22).

If the replacement is found to be completed (S22: Yes), the substrate processing system 1 lowers the pressure within the main body 31 to the atmospheric pressure and ends the drying processing (S23).

If the replacement is not completed (S22: No), the substrate processing system 1 makes the determination upon whether the completion time has passed by after the drying processing is begun (S24).

If the completion time has not elapsed (S24: No), the substrate processing system 1 carries on the drying processing. If the completion time has elapsed (S24: Yes), the substrate processing system 1 notifies the occurrence of the abnormality in the drying processing through the notification unit 78 (S25).

<Effects of Second Exemplary Embodiment>

The substrate processing system 1 images the supercritical fluid by the camera 77, and detects the completion of the replacement of the IPA with the supercritical fluid by comparing the obtained image data and the reference image data. Thus, the IPA can be replaced by the supercritical fluid accurately. Further, since the pressure within the main body 31 can be reduced at the timing when the replacement of the IPA by the supercritical fluid is completed, the drying processing can be completed in a short time period if the replacement is completed before the lapse of the completion time.

### MODIFICATION EXAMPLES

In the above-described exemplary embodiments, the acquisition device 75 acquires the optical information upon the supercritical fluid by imaging the supercritical fluid with the camera 77. However, the optical information upon the supercritical fluid may be obtained by measuring an absorbance by, for example, a spectrophotometer. In this case, the determination unit 19C determines whether the IPA on the wafer W has been replaced with the supercritical fluid based on the absorbance. Further, the acquisition device 75 may acquire the optical information upon the supercritical fluid based on reflection light from the supercritical fluid.

Further, the acquisition device 75 may be equipped with both the camera 77 and the spectrophotometer, and the determination unit 19C may determine whether the IPA on the wafer W has been replaced by the supercritical fluid based on the image data obtained by the camera 77 and the absorbance.

In addition, the determination unit 19C may learn, by mechanical learning such as deep learning, a characteristic amount of the image data on which the IPA on the wafer W is replaced by the supercritical fluid, and determine whether the IPA on the wafer W has been replaced by the supercritical fluid based on the image data obtained by the camera 77.

Furthermore, in the above-described exemplary embodiments, the determination unit 19C determines whether the IPA on the wafer W has been replaced by the supercritical fluid. However, through the imaging by the camera 77, it may be determined, as the determination upon the presence or absence of the liquid, whether the inside of the main body 31 is filled with the supercritical fluid. Since a density of the fluid within the main body 31 changes before and after the inside of the main body 31 is filled with the supercritical fluid, the images obtained by the camera 77 may be different before and after the inside of the main body 31 is filled with the supercritical fluid.

The determination unit 19C may store the image data obtained before (or after) the inside of the main body 31 is filled with the supercritical fluid, and determine whether the inside of the main body 31 has been filled with the supercritical fluid by comparing the stored image data and the image data obtained by the imaging through the camera 77.

Moreover, when an abnormality has occurred in the drying processing unit 17, a bubble may be generated. If the bubble is observed on the image obtained by the camera 77, the determination unit 19C may make the determination that the drying processing unit 17 is abnormal and make the alarm indicating the abnormality by the notification unit 78.

In addition, the processings in the controller 19 according to the exemplary embodiments may be performed in a combined manner or a separate manner. By way of example, the instruction unit 19A and the output unit 19D may be combined as a single output unit.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

### EXPLANATION OF CODES

1: Substrate processing system (substrate processing apparatus)

4: Control device

16: Cleaning processing unit

17: Drying processing unit (drying processor)

19: Controller

19A: Instruction unit

19B: Input unit

19C: Determination unit (detector)

19D: Output unit

20: Storage unit

63: Cleaning liquid source (cleaning liquid supply)

70: Sight glass

72: Transmitting window

75: Acquisition device

77: Camera

78: Notification unit

L1: Supply line

L2: Drain line

L3: Cleaning liquid supply line

L4: Cleaning liquid drain line

1. A substrate processing apparatus, comprising:
a drying processor configured to perform, by bringing a supercritical fluid into contact with a substrate having a surface wet by a liquid to replace the liquid with the supercritical fluid, a drying processing on the substrate;
a drain line through which the fluid is drained from the drying processor, the drain line being provided in the drying processor;
an acquisition unit configured to acquire optical information upon the fluid drained from the drying processor, the acquisition unit being provided on the drain line; and
a detector configured to detect presence or absence of the liquid within the drying processor based on the optical information acquired by the acquisition unit.

2. The substrate processing apparatus of claim 1, further comprising:
a notification unit configured to make a notification when the liquid is found not to be replaced with the supercritical fluid even after a lapse of a preset time after the drying processing is begun as a result of the detection upon the presence or absence of the liquid within the drying processor by the detector.

3. The substrate processing apparatus of claim 1,
wherein the detector detects replacement completion of the liquid with the supercritical fluid based on the optical information, and
the drying processor ends the drying processing when the replacement completion is detected by the detector.

4. The substrate processing apparatus of claim 1,
wherein the acquisition unit acquires image data by imaging the fluid drained from the drying processor, and
the detector detects the presence or absence of the liquid within the drying processor based on the image data.

5. The substrate processing apparatus of claim 1,
wherein the acquisition unit measures an absorbance upon the fluid drained from the drying processor, and
the detector detects the presence or absence of the liquid within the drying processor based on the absorbance.

6. The substrate processing apparatus of claim 1, further comprising:
a transmitting window configured to transmit light when the optical information is acquired by the acquisition unit, the transmitting window being provided on the drain line, and
a cleaning liquid supply configured to supply a cleaning liquid configured to clean the transmitting window into the drain line.

7. A substrate processing method, comprising:
drying a substrate, whose surface is wet by a liquid, by bringing a supercritical fluid into contact with the substrate to replace the liquid with the supercritical fluid;
acquiring, on a drain line through which the fluid is drained from a drying processor configured to perform the drying of the substrate, optical information upon the fluid drained from the drying processor; and
detecting presence or absence of the liquid within the drying processor based on the optical information.

8. The substrate processing apparatus of claim 2,
wherein the detector detects replacement completion of the liquid with the supercritical fluid based on the optical information, and
the drying processor ends the drying processing when the replacement completion is detected by the detector.

9. The substrate processing apparatus of claim 8,
wherein the acquisition unit acquires image data by imaging the fluid drained from the drying processor, and
the detector detects the presence or absence of the liquid within the drying processor based on the image data.

10. The substrate processing apparatus of claim 9,
wherein the acquisition unit measures an absorbance upon the fluid drained from the drying processor, and
the detector detects the presence or absence of the liquid within the drying processor based on the absorbance.

11. The substrate processing apparatus of claim 10, further comprising:
a transmitting window configured to transmit light when the optical information is acquired by the acquisition unit, the transmitting window being provided on the drain line, and
a cleaning liquid supply configured to supply a cleaning liquid configured to clean the transmitting window into the drain line.
